(19) United States
(12) Patent Application Publication
(10) Pub. No.: US 2022/0285597 A1
(43) Pub. Date: Sep. 8, 2022

(54) Display Device

(71) Applicant: Darwin Precisions Corporation, Hsinchu County (TW)

(72) Inventors: YU JEN LAI, Hsinchu County (TW); YA HAN KO, Hsinchu County (TW)

(21) Appl. No.: 17/681,912

(22) Filed: Feb. 28, 2022

(30) Foreign Application Priority Data
Mar. 3, 2021 (TW) 110107599

(51) Int. Cl. H01L 33/62; H01L 33/58; H01L 33/36

(52) U.S. Cl. CPC H01L 33/62; H01L 33/58; H01L 33/36

(57) ABSTRACT

A display device is disclosed. The display device includes a substrate and a LED device. The substrate includes a translucent body and a conductive wire layer. The translucent body has a translucent body first surface. The conductive wire layer is disposed on the translucent body first surface. The LED device includes a base and a LED chip. The base is disposed on the other side of the conductive wire layer with respect to the translucent body and is coupled with the conductive wire layer. The base has a base first surface facing the translucent body first surface. The LED chip is disposed on the base first surface.

### BACKGROUND

### Technical Field

The present invention relates to a display device, and specifically, to a transparent display device.

### Related Art

With the progress of display technologies, transparent display devices have been developed. With a certain extent of translucence, users can see clearly images of objects behind the transparent display devices. Hence, transparent display devices could be used in house windows, vehicle windows, shop windows, etc., and they have been attracting attention from the market.

As shown in FIG. 1, in conventional transparent display devices, LEDs are disposed on one side of the board 10 with their light emitting direction toward the users/watchers, wherein the other side of the board 10 is disposed on the glass 80 for support. Since the LEDs 20 and the users/watchers (symbol 60 represents the eyes of the users/watchers) are on the same side of the glass 80, the LEDs are more susceptible to external forces such as collisions from the user/viewer side, which increases the chance of damage and reduces durability.

### SUMMARY

One of the objectives of the present invention is to provide a display device having better durability.

The display device of the present invention includes a substrate and an LED device. The substrate includes a translucent body and a conductive wire layer. The translucent body has a translucent body first surface. The conductive wire layer is disposed on the translucent body first surface. The LED device includes a base and a LED chip. The base is disposed on the other side of the conductive wire layer with respect to the translucent body and is coupled with the conductive wire layer. The base has a base first surface facing the translucent body first surface. The LED chip is disposed on the base first surface.

### BRIEF DESCRIPTION OF THE DRAWINGS

FIG. 1 is a schematic diagram of prior art.

FIG. 2 is a schematic diagram of an embodiment of a display device.

FIG. 3 is a schematic diagram of another embodiment of a display device.

FIG. 4 is a schematic diagram of another embodiment of a display device.

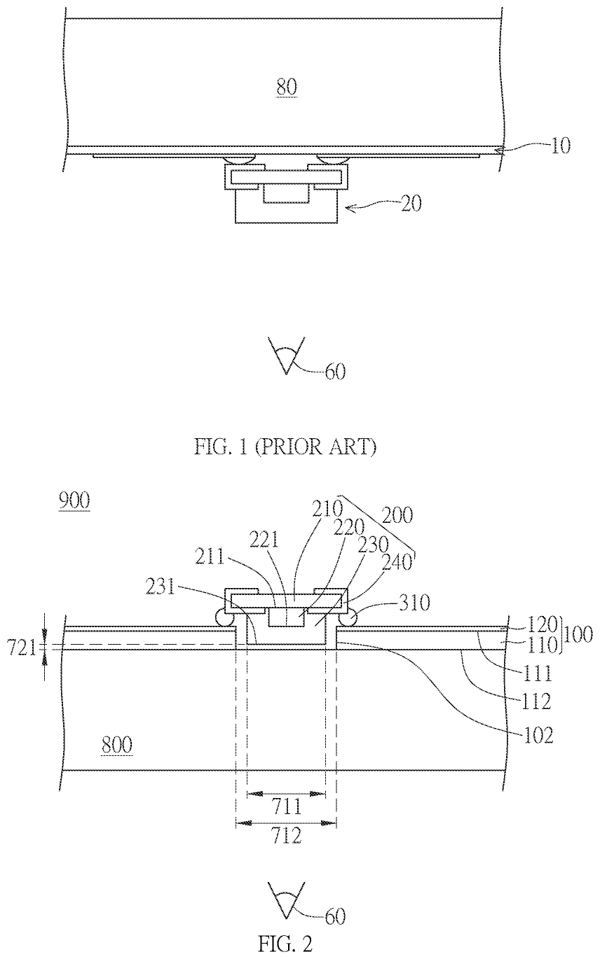

### DETAILED DESCRIPTION

Implementations of a connection assembly disclosed by the present invention are described below by using particular and specific embodiments with reference to the drawings, and a person skilled in the art may learn of advantages and effects of the present invention from the disclosure of this specification. However, the following disclosure is not intended to limit the protection scope of the present invention, and a person skilled in the art may carry out the present invention by using other different embodiments based on different viewpoints without departing from the concept and spirit of the present invention. In the accompanying drawings, plate thicknesses of layers, films, panels, regions, and the like are enlarged for clarity. Throughout the specification, same reference numerals indicate same elements. It should be understood that when an element such as a layer, film, region or substrate is referred to as being “on” or “connected” to another element, it may be directly on or connected to the another element, or intervening elements may also be present. In contrast, when an element is referred to as being “directly on” or “directly connected to” another element, there is no intervening element present. As used herein, “connection” may refer to a physical and/or electrical connection. Further, “electrical connecting” or “coupling” may indicate that another element exists between two elements.

It should be noted that the terms “first”, “second”, “third”, and the like that are used in the present disclosure can be used for describing various elements, components, regions, layers and/or portions, but the elements, components, regions, layers and/or portions are not limited by the terms. The terms are merely used to distinguish one element, component, region, layer, or portion from another element, component, region, layer, or portion. Therefore, the “first element”, “component”, “region”, “layer”, or “portion” discussed below may be referred to as a second element, component, region, layer, or portion without departing from the teaching of this disclosure.

In addition, relative terms, such as “down” or “bottom” and “up” or “top”, are used to describe a relationship between an element and another element, as shown in the figures. It should be understood that the relative terms are intended to include different orientations of a device in addition to orientations shown in the figures. For example, if a device in a figure is turned over, an element that is described to be on a “lower” side of another element is directed to be on an “upper” side another element. Therefore, the exemplary terms “down” may include orientations of “down” and “up” and depends on a particular orientation of an accompanying drawing. Similarly, if a device in a figure is turned over, an element that is described as an element “below” another element or an element “below” is directed to be “above” another element. Therefore, the exemplary terms “below” or “below” may include orientations of up and down.

As used herein, “about”, “approximately”, or “substantially” is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, ±20%, ±10%, ±5% of the stated value. Further, as used herein, “about”, “approximately”, or “substantially” may depend on optical properties, etch properties, or other properties to select a more acceptable range of deviations or standard deviations without one standard deviation for all properties.

As shown in the embodiment in FIG. 2, the display device 900 of the present invention includes a substrate 100 and an LED device 200. The substrate 100 includes a translucent body 110 and a conductive wire layer 120. The translucent body 110 has a translucent body first surface 111. The conductive wire layer 120 is disposed on the translucent body first surface 111. More particularly, the translucent body 110 is translucent, and the conductive wire layer 120 is composed of conductive wires. In an embodiment, the translucent body 110 is a polymer film made from transparent material such as polyethylene terephthalate, polyvinyl chloride, polyimide, etc. The conductive wire layer 120 is composed of conductive wires made from transparent material such as indium tin oxide, antimony doped tin oxide, metal-doped ZnO, etc. In different embodiments, the conductive wire layer 120 could contain transparent or non-transparent wires made from conductive silver paste or conductive ink materials. The display device 900 further includes a translucent board 800 disposed on the side of the translucent body 110 opposite to the translucent body first surface 111.

As shown in the embodiment in FIG. 2, the LED device 200 includes a base 210 and a LED chip 220. The base 210 is disposed on the side of the conductive wire layer 120 opposite to the side of the translucent body 110 and is coupled with the conductive wire layer 120. The base 210 has a base first surface 211 facing the translucent body first surface 111. The base 210 can be plate-shaped or cup-shaped. The LED chip 220 is disposed on the base first surface 211.

The translucent body 110 further has a translucent body second surface 112 opposite to the translucent body first surface 111. The LED chip 220 further has a chip light emitting surface 221, wherein the chip light emitting surface 221 and the translucent body second surface 112 face the same direction. The chip light emitting surface 221 doesn't protrude from the translucent body second surface 112.

More particularly, the LED device 200 further includes a package body 230 and an LED electrode 240. The package body 230 is disposed on the base first surface 211 and covers the LED chip 220. The package body 230, for example, could be transparent, semitransparent, or fluorescent, and could be mixed with a wavelength conversion material such as a phosphorescent material. The package body 230 could be made from silicon resin, epoxy, glass, plastic, or other materials. The side of the package body 230 opposite to the base first surface 211 has a package body light emitting surface 231. The LED electrode 240 is disposed at the edge of the base 210 and is coupled respectively with the LED chip 220 and the conductive wire layer 120.

Accordingly, in the transparent display device 220 of the present invention, the LED device 200 is disposed on the substrate 100 with its light emitting direction toward the translucent board 800. The light emitted by the LED device 200 passes through the translucent board 800 so that it could be seen by the users/watchers on the other side of the translucent board 800, wherein the symbol 60 represents the eyes of the users/watchers. Since the LED device 200 and the users are on different sides of the translucent board 800, the chance of the LED device 200 being collided and damaged by forces from the user's side could be reduced. Hence, its durability is enhanced.

More particularly, as shown in the embodiment in FIG. 2, the substrate 100 includes a substrate hole 102, wherein at least a portion of the package body 230 is accommodated in the substrate hole 102. The translucent body 110 and the conductive wire layer 120 respectively have a hollow portion wherein the orthographic projections of the hollow portions on the translucent board 800 overlap with each other, and the hollow portions together form the substrate hole 102. The substrate hole 102 can be formed by perforating the substrate 100 after the conductive wire layer 120 is disposed on the translucent body 110. In different processes, one can perforate the translucent body 110 first and then dispose the conductive wire layer 120 in locations other than the perforated hole, wherein the perforated hole on the translucent body 110 are substantially the substrate hole 102.

As shown in the embodiment in FIG. 2, the display device 200 is disposed on the substrate 100 with the package body light emitting surface 231 facing the translucent board 800, wherein the package body 230 is accommodated in the substrate hole 102. In other words, at least a portion of the display device 200 is accommodated in the substrate hole 102. Thus, the thickness of the display device 900 can be reduced. The LED electrode 240 can be coupled with the conductive wire layer 120 via solder or conductive paste 310. The package body light emitting surface 231 has a first width 711. The substrate hole 102 has a second width 712 larger than the first width 711, which allows the package body 230 to be accommodated in the substrate hole 102.

In an embodiment, the package body light emitting surface 231 is a square. The first width 711 is the side length. The substrate hole 102 is a square or a circle, wherein the second width 712 could be respectively the side length of the square or the diameter of the circle. When the first width 711 is less than 2 mm, the difference between the second width 712 and the first width 711 is between 0.1 mm and 0.5 mm. When the first width 711 is between 2 mm and 5 mm, the difference between the second width 712 and the first width 711 is between 0.1 mm and 1.5 mm. When the first width 711 is larger than 5 mm, the difference between the second width 712 and the first width 711 is between 0.2 mm and 4 mm. Accordingly, the package body 230 can be accommodated in the substrate hole 102 more easily. Contact or collision between the package body 230 and the side wall of the substrate hole 102 could be prevented.

As shown in the embodiment in FIG. 2, to dispose the substrate 100 on the translucent board 800 while preventing collision between the package body 230 and the translucent board 800, it is preferable that the substrate 100 has a certain thickness. More particularly, the translucent body 110 has a translucent body second surface 112 opposite to the translucent body first surface 111. There is a first distance 721 between the package body light emitting surface 231 and the translucent body second surface 112 along the direction perpendicular to the translucent body second surface 112, i.e., the first distance 721 is the distance between the package body light emitting surface 231 and the translucent board 800. When the first width 711 is less than 2 mm, the first distance 721 is larger than 0.1 mm. When the first width 711 is between 2 mm and 5 mm, the first distance 721 is larger than 0.1 mm. When the first width 711 is larger than 5 mm, the first distance 721 is larger than 0.2 mm.

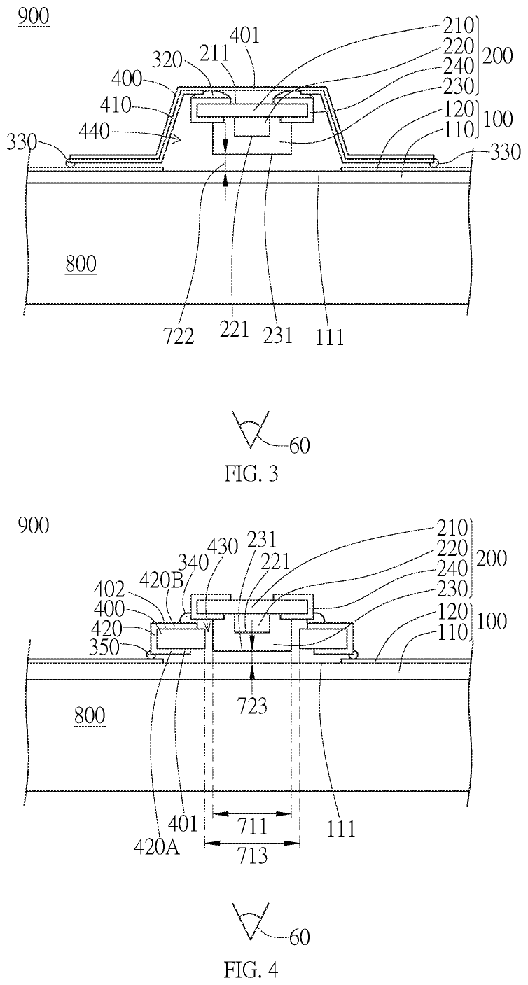

In different embodiments, for reasons such as inconvenience to perforate the substrate 100, the LED device 200 could be disposed indirectly on the substrate 100 by other means. As shown in the embodiment in FIG. 3, the display device 900 further comprises an adapting device 400 disposed on the side of the conductive wire layer 120 opposite to the translucent body 110. The LED device 200 is disposed on the adapting device 400. The adapting device 400 includes an adapting electrode 410, wherein the LED electrode 240 is coupled with the conductive wire layer 120 via the adapting electrode 410.

More particularly, as shown in the embodiment in FIG. 3, the adapting device 400 is a bracket having an adapting device first surface 401 facing the translucent body 110. The adapting electrode 410 is disposed on the adapting device first surface 401, wherein the adapting device first surface 401 forms a concave portion 420 away from the translucent body 110. The LED device 200 is disposed in the concave portion 420. The LED electrode 240 can be coupled with the adapting electrode 410 via solder 320. The adapting electrode 410 can be coupled with the conductive wire layer 120 via solder 330. Accordingly, the LED electrode 240 can be coupled with the conductive wire layer 120. The adapting device 400 in the form of a bracket could be modified according to the manufacturing, design, and usage requirements. For example, the shape or the way that the adapting electrode 410 being disposed could be modified.

As shown in the embodiment in FIG. 3, to prevent collision between the package body 230 and the translucent body 110, it is preferable that the concave portion 420 has certain depth. More particularly, there is a second distance 722 between the package body light emitting surface 231 and the translucent body first surface 111. When the first width 711 is less than 2 mm, the second distance 722 is larger than 0.1 mm. When the first width 711 is between 2 mm and 5 mm, the second distance 722 is larger than 0.1 mm. When the first width 711 is larger than 5 mm, the second distance 722 is larger than 0.2 mm.

In different embodiments, for reasons such as reducing manufacturing cost, common components can be used as the adapting device 400. As shown in the embodiment in FIG. 4, the adapting device 400 is a circuit board having an adapting device first surface 401 and an adapting device second surface 402 disposed on opposite sides. The adapting device first surface 401 faces the translucent body 110. The adapting electrode 420 extends from the adapting device first surface 401 toward the adapting device second surface 402. Since circuit boards are common components with a mature manufacturing process and quality stability, using circuit boards as the adapting devices 400 can reduce design and manufacturing cost.

More particularly, the portion 420A of the adapting electrode 420 on the adapting device first surface 401 and the portion 420B of the adapting electrode 420 on the adapting device second surface 402 are respectively coupled with the conductive wire layer 120 and the LED electrode 240. The LED electrode 240 can be coupled with the portion 420B of the adapting electrode 420 on the adapting device second surface 402 via solder 340. The portion 420A of the adapting electrode 420 on the adapting device first surface 401 can be coupled with the conductive wire layer 120 via solder 350. Accordingly, the LED electrode 240 can be coupled with the conductive wire layer 120.

As shown in the embodiment in FIG. 4, the adapting device 400 includes an adapting device hole 430. At least a portion of the package body 230 is accommodated in the adapting device hole 430. The package body light emitting surface 231 has a first width 711. The adapting device hole 430 has a third width 713 larger than the first width 711, which allows the package body 230 to be accommodated in the adapting device hole 430.

In an embodiment, the package body light emitting surface 231 is a square. The first width 711 is the side length. The adapting device hole 430 is a square or a circle, wherein the third width 713 could be the side length of the square or the diameter of the circle. When the first width 711 is less than 2 mm, the difference between the third width 713 and the first width 711 is between 0.1 mm and 0.5 mm. When the first width 711 is between 2 mm and 5 mm, the difference between the third width 713 and the first width 711 is between 0.1 mm and 1.5 mm. When the first width 711 is larger than 5 mm, the difference between the third width 713 and the first width 711 is between 0.2 mm and 4 mm. Accordingly, the package body 230 can be accommodated in the adapting device hole 430 more easily. Contact or collision between the package body 230 and the side wall of the adapting device hole 430 could be prevented.

As shown in the embodiment in FIG. 4, to prevent collision between the package body 230 and the translucent body 110, there is preferable a certain distance between the two. More particularly, in an embodiment, there is a third distance 723 between the package body light emitting surface 231 and the translucent body first surface 111. When the first width 711 is less than 2 mm, the third distance 723 is larger than 0.1 mm. When the first width 711 is between 2 mm and 5 mm, the third distance 723 is larger than 0.1 mm. When the first width 711 is larger than 5 mm, the third distance 723 is larger than 0.2 mm.

The present invention is described by means of the above-described relevant embodiments. However, the above-described embodiments are only examples for implementing the present invention. It should be pointed out that the disclosed embodiments do not limit the scope of the present invention. In contrast, the spirit included in the scope of the patent application and modifications and equivalent settings made within the scope are all included in the scope of the present invention.

What is claimed is:

1. A display device, comprising:
a substrate, wherein the substrate includes:
a translucent body having a translucent body first surface; and
a conductive wire layer disposed on the translucent body first surface; and
an LED device, wherein the LED device includes:
a base, wherein the base is disposed on the other side of the conductive wire layer with respect to the translucent body and is coupled with the conductive wire layer, wherein the base has a base first surface facing the translucent body first surface; and
an LED chip disposed on the base first surface.

2. The display device according to claim 1, wherein the translucent body has a translucent body second surface opposite to the translucent body first surface, wherein the LED chip has a chip light emitting surface, wherein the chip light emitting surface and the translucent body second surface face the same direction, wherein the chip light emitting surface doesn't protrude from the translucent body second surface.

3. The display device according to claim 1, wherein the LED device further includes:
a package body, wherein the package body is disposed on the base first surface and covers the LED chip, wherein one side of the package body opposite to the base first surface has a package body light emitting surface; and
an LED electrode disposed on the base and is coupled respectively with the LED chip and the conductive wire layer.

4. The display device according to claim 3, wherein the substrate includes a substrate hole, wherein at least a portion of the package body is accommodated in the substrate hole.

5. The display device according to claim 4, wherein the package body light emitting surface has a first width, the substrate hole has a second width larger than the first width, wherein:
when the first width is less than 2 mm, the difference between the second width and the first width is between 0.1 mm and 0.5 mm;
when the first width is between 2 mm and 5 mm, the difference between the second width and the first width is between 0.1 mm and 1.5 mm;
when the first width is larger than 5 mm, the difference between the second width and the first width is between 0.2 mm and 4 mm.

6. The display device according to claim 5, wherein the translucent body has a translucent body second surface opposite to the translucent body first surface, wherein there is a first distance between the package body light emitting surface and the translucent body second surface along a direction perpendicular to the translucent body second surface, wherein:
when the first width is less than 2 mm, the first distance is larger than 0.1 mm;
when the first width is between 2 mm and 5 mm, the first distance is larger than 0.1 mm;
when the first width is larger than 5 mm, the first distance is larger than 0.2 mm.

7. The display device according to claim 5, further comprises an adapting device disposed on the opposite side of the conductive wire layer with respect to the translucent body, wherein the LED device is disposed on the adapting device, wherein the adapting device includes an adapting electrode, wherein the LED electrode is coupled with the conductive wire layer via the adapting electrode.

8. The display device according to claim 7, wherein the adapting device is a bracket having an adapting device first surface facing the translucent body, wherein the adapting electrode is disposed on the adapting device first surface, wherein the adapting device first surface forms a concave portion away from the translucent body, wherein the LED device is disposed in the concave portion.

9. The display device according to claim 8, wherein there is a second distance between the package body light emitting surface and the translucent body first surface, wherein:
when the first width is less than 2 mm, the second distance is larger than 0.1 mm;
when the first width is between 2 mm and 5 mm, the second distance is larger than 0.1 mm;
when the first width is larger than 5 mm, the second distance is larger than 0.2 mm.

10. The display device according to claim 7, wherein the adapting device is a circuit board having an adapting device first surface and an adapting device second surface disposed in opposite sides, wherein the adapting device first surface faces the translucent body, wherein the adapting electrode extends from the adapting device first surface to the adapting device second surface, wherein the portion of the adapting electrode on the adapting device first surface and the portion of the adapting electrode on the adapting device second surface are respectively coupled with the conductive wire layer and the LED electrode, wherein the adapting device includes an adapting device hole, wherein at least a portion of the package body is accommodated in the adapting device hole.

11. The display device according to claim 10, wherein the package body light emitting surface has a first width, the adapting device hole has a third width larger than the first width, wherein:
when the first width is less than 2 mm, the difference between the third width and the first width is between 0.1 mm and 0.5 mm;
when the first width is between 2 mm and 5 mm, the difference between the third width and the first width is between 0.1 mm and 1.5 mm;
when the first width is larger than 5 mm, the difference between the third width and the first width is between 0.2 mm and 4 mm.
